(19) United States
(12) Patent Application Publication
(10) Pub. No.: US 2014/0273354 A1
(43) Pub. Date: Sep. 18, 2014

(54) FABRICATION OF 3D CHIP STACKS WITHOUT CARRIER PLATES

(71) Applicant: APPLIED MATERIALS, INC., Santa Clara, CA (US)

(72) Inventors: Sesh RAMASWAMI, Saratoga, CA (US); Chin Hock TOH, Singapore (SG); Niranjan KUMAR, Santa Clara, CA (US)

(73) Assignee: APPLIED MATERIALS, INC., Santa Clara, CA (US)

(21) Appl. No.: 13/841,418

(22) Filed: Mar. 15, 2013

(51) Int. Cl. H01L 21/52; H01L 21/302

(52) U.S. Cl. CPC H01L 21/52; H01L 21/302
USPC 438/126

(57) ABSTRACT

A method of fabricating a 3D chip stack uses an interposer and an electronic circuit substrate comprising a plurality of electronic circuits. The electrical contacts of the electronic circuit substrate are bonded and electrically coupled to bumps of the interposer. A molding compound is applied over the electronic circuits to form a molded structure. The molded structure is thinned to have a second molded thickness that is less than the first molded thickness, and the interposer is thinned to a second interposer thickness that is less than a first interposer thickness.

### BACKGROUND

Embodiments of the present invention relate to 3D chip stacks and their fabrication processes.

Three-dimensional (3D) chip stacks comprising vertically stacked substrates that contain electronic circuits, interconnect lines and through-silicon vias. 3D stacks provide higher areal densities, a smaller footprint, faster operating speeds by increasing interconnect bandwidth and reducing wire delay by shortening the electrical paths between the vertically stacked structures, and improved power efficiency. Conventional 3D chip stack structures are commonly known as 3D packages, System in Package, or Chip Stack MCM. The 3D chip stacks can include applications such as for example, programmable gate arrays, DRAM memories, and logic-memory stacks for mobile applications.

A typical 3D chip comprises an electronic circuit substrate (EC substrate), which is also known as an active die, and includes for example, a plurality of electronic circuits such as integrated, display, memory, power, and photovoltaic circuits. Each electronic circuit comprises active and passive features embedded into an EC substrate such as a silicon wafer or a glass substrate coated with silicon. The interposer of the 3D chip stack contains electrically conducting through-silicon vias (TSV) which extend therethrough and interconnect lines to electrically connect the active and passive features of the overlying electronic circuits of the EC substrate. An interposer is fabricated by etching multiple layers of interconnect lines and through-silicon vias in an interposer substrate such as a silicon wafer or glass panel with a silicon layer. Dielectric layers such as silicon oxide and silicon nitride layers are used to line the walls of the etched through-silicon vias to serve as diffusion or insulator barriers, and hermetic and permeation-reducing layers. The dielectric coated vias are then filled with an electrical conductor such as a metal, for example, aluminum, copper, silver, and gold, to form the through-silicon vias. These through-silicon vias serve as vertical electrical connections between the electronic circuits of the overlying electronic circuit substrate, interconnect lines in the interposer, and the outside environment to connect the electronic circuits to power, signal and ground interconnects on a printed circuit board.

In conventional 3D chip stack fabrication methods, an electronic circuit substrate is bonded to a carrier plate to provide structural support and then thinned to reduce its thickness by planarizing the EC substrate. For example, the EC substrate can be thinned from a thickness of 700 to 800 microns to about 50 to 500 microns. The thinned EC substrate with its embedded electronic circuits is then bonded and electrically connected to the interconnect lines and through-silicon vias of an interposer. However, the thinned EC substrate is susceptible to warping making it difficult to attach a warped die to a planar interposer. To compensate for the warping, the thinned EC substrate is often pressed down onto the interposer leading to cracking of the EC substrate. Alternatively, solder interconnect bumps on the EC substrate are made thicker to accommodate for the variation in thickness caused by warping, which leads to additional fabrication complications. The thinned EC substrate is also often encapsulated with an epoxy material, which when cured, impart stresses and cause the EC substrate to bow, again making it difficult to attach and connect the bowed EC substrate to the interposer. Epoxies also absorb moisture which make subsequent high-vacuum processes difficult to conduct due to out-gassing of the moisture, and which can also encourage moisture absorption across the several square centimeters of area of these materials.

Still further, the interposer of the 3D chip stack also needs to be thinned (for example to less than 100 microns) to reveal the exposed surfaces of the through-silicon vias for electrically connections to the vias. Prior to thinning, the interposer is also temporarily bonded to a carrier plate which provides structural support for the thinning process, thinned, and then de-bonded. However, each bonding and de-bonding step to a carrier plate adds process complexity and reduces manufacturing yields.

Thus, for various reasons that include these and other deficiencies, and despite the development of various methods of fabricating 3D chip stacks with an EC substrate active an interposer, further improvements in the fabrication and packaging of the 3D chip stacks are continuously being sought.

### SUMMARY

A method of fabricating a 3D chip stack, comprises providing an interposer having a first interposer thickness, a front surface comprising bumps, and a back surface, and providing an electronic circuit substrate comprising a plurality of electronic circuits and a connector surface having electrical contacts. The electrical contacts of the connector surface of the electronic circuit substrate are bonded and electrically coupled to the bumps of the interposer. A molding compound is applied over the electronic circuits to form a molded structure having a first molded thickness. The molded structure is thinned to have a second molded thickness that is less than the first molded thickness. The interposer is thinned to form a thinned interposer having a second interposer thickness that is less than the first interposer thickness.

In another method of fabricating a 3D chip stack, an interposer is prefabricated to have a plurality of through-silicon vias. The electrical contacts of the connector surface of the electronic circuit substrate are bonded and electrically coupled to the bumps of the interposer. A molding compound is applied over the electronic circuits to form a molded structure having a first molded thickness. The molded structure is thinned to a second molded thickness that is less than the first molded thickness and to expose top surfaces of the electronic circuits. The interposer is thinned to form a thinned interposer having a second interposer thickness that is less than the first interposer thickness and to expose contact regions of the through-silicon vias.

In yet another method of fabricating a 3D chip stack, the interposer is initially absent through-silicon vias. The electrical contacts of the connector surface of the electronic circuit substrate are bonded and electrically coupled to the bumps of the interposer, and a molding compound is applied over the electronic circuits to form a molded structure having a first molded thickness. The molded structure is thinned to a second molded thickness that is less than the first molded thickness and to expose top surfaces of the electronic circuits. The interposer is thinned to form a thinned interposer having a second interposer thickness that is less than the first interposer thickness. Thereafter, a plurality of through-silicon vias are formed in the thinned interposer by etching holes through a back surface of the thinned interposer and depositing an oxide liner and metal into the etched holes.

### DRAWINGS

These features, aspects and advantages of the present invention will become better understood with regard to the following description, appended claims, and accompanying drawings, which illustrate examples of the invention. However, it is to be understood that each of the features can be used in the invention in general, not merely in the context of the particular drawings, and the invention includes any combination of these features, where:

FIG. 1A is a schematic sectional diagram of an interposer comprising through-silicon vias, interconnects and bumps of a bump connector pad;

FIG. 1B is a schematic sectional diagram showing bonding and electrical coupling of the interposer to the electronic circuits of an electronic circuit substrate;

FIG. 1C is a schematic sectional diagram of the molded structure of the electronic circuit substrate attached to the interposer after thinning of the molding compound and electronic circuit substrate;

FIG. 1D is a schematic sectional diagram showing a thinned interposer attached to a thinned electronic circuit substrate;

FIG. 1E is a schematic sectional diagram of contact bumps formed on the thinned interposer;

FIG. 1F is a schematic sectional diagram showing a heat sink attached to the electronic circuits to form a completed 3D chip stack;

FIG. 2A is a schematic sectional diagram of a partially fabricated interposer comprising interconnects and bumps of a bump connector pad, but which is absent through-silicon vias and which is used for a via-last process;

FIG. 2B is a schematic sectional diagram showing bonding and electrical coupling of the partially fabricated interposer to the electronic circuits of an electronic circuit substrate;

FIG. 2C is a schematic sectional diagram of the molded structure of the electronic circuit substrate attached to the partially fabricated interposer after thinning of the molding compound and electronic circuit substrate;

FIG. 2D is a schematic sectional diagram showing a thinned interposer attached to a thinned electronic circuit substrate showing fabrication of the through-silicon vias in a via-last process;

FIG. 2E is a schematic sectional diagram of contact bumps formed on the thinned and finished interposer;

FIG. 2F is a schematic sectional diagram showing a heat sink attached to the electronic circuits to form a completed 3D chip stack made with the via-last process; and

FIG. 3 is a flowchart of exemplary processes for fabricating a 3D chip stack.

### DESCRIPTION

An exemplary embodiment of a process capable of fabricating a 3D chip stack 20 comprising an interposer 22 and an electronic circuit substrate 24 having electronic circuits 26, without the use of carrier plates, is illustrated with reference to FIGS. 1A to 1F and FIG. 3. The carrier-plate-less process significantly reduces the process steps required to fabricate 3D chip stack structures. The flow chart of FIG. 3 shows two exemplary processes, the first represented by the path of the solid arrows is a via-middle process in which an interposer 22 is prefabricated with through-silicon vias 28, and the second as represented by the path of the broken arrows is a via-last process in which the through-silicon vias 28a are fabricated in a later process step after thinning of the interposer 22. While exemplary and illustrative process sequences and steps are described herein, it should be understood that other process sequences or steps as would be apparent to those of ordinary skill in the art can also be used, and all such processes fall within the scope of the present invention. For example, the exemplary process steps described herein can be performed in different sequences, substituted with other process steps, or process steps can be eliminated, without deviating from the scope of the present claims. Thus the claims should not be limited to the exemplary and illustrative processes and apparatus described herein.

In the exemplary first (or via-middle) fabrication process, an interposer 22 comprising electrically conducting through-silicon vias (TSVs) 28 is fabricated on a silicon plate 30 using sequentially performed processes. The silicon plate 30 can be for example, glass, polycrystalline silicon, a silicon wafer composed of monocrystalline silicon, or other forms of crystalline or amorphous silicon. The interposer 22 has a front surface 32 and a back surface 34, as shown in FIG. 1A, and has a first interposer thickness T_{I1} that is typically the full or original thickness of the original silicon plate 30 but can also be a smaller thickness than the original thickness. A typical first thickness of the silicon plate 30 is from about 500 to about 1000 microns.

One or more features 36 are etched into the front surface 32 of the silicon plate 30 using photolithography and conventional etching processes such that the features 36 have substantially uniform depths through the thickness of the silicon plate 30. In one version, the etched features 36 include holes 37 having a diameter of from about 5 to about 50 microns and a depth of from about 10 to about 500 microns. A suitable conventional etching process comprises dry reactive ion etching of silicon with specialized gaseous ions. After etching, a conformal oxide liner (not shown) such as for example silicon dioxide, is deposited into the holes 37 by a conventional (chemical vapor deposition) CVD process to electrically isolate the holes 37 from the surrounding material. Conventional physical vapor deposition (PVD) processes are then used to deposit seed and barrier films into the holes 37. The holes 37 are then filled with a metal such as copper, using another conventional PVD process, to form electrically conducting through-silicon vias 28. The metal can be deposited into the holes 37 by electroplating in a low overburden process to minimize the variation in the thickness of the copper across the silicon plate 30 to allow more efficient planarization of these surfaces by subsequently performed chemical mechanical processes (CMP).

After the through-silicon vias 28 are formed, a plurality of interconnects 40 are fabricated within deposited dielectric layers to be aligned and electrically connected to the through-silicon vias 28. The dielectric layers can be made from silicon nitride deposited by CVD processes. Suitable interconnects 40 can include an electrically conductive material such as aluminum or copper, and have typical dimensions of from about 0.5 to about 5 microns with an aspect ratio of from about 1 to about 2. A suitable dual-damascene process for fabricating the interconnects 40 comprises a conventional copper damascene process. After fabrication of interconnects 40, a thin final passivation layer (not shown) is deposited over the interconnects 40 to protect these fine-line structures from subsequent process steps and exposure. A suitable passivation layer comprises silicon nitride, silicon oxide, or a polymer deposited using a conventional CVD process or other coating methods such as a flowable process or a spin-on process. Thereafter, a pad opening process is conducted using conventional lithography processes to form exposed contact regions (not shown) that extend through the passivation layer to contact the underlying interconnects 40. Thereafter, an under bump metal layer is deposited over the entire surface of the interposer 22 using conventional PVD processes. The under bump metal layer can include an initially deposited barrier layer of titanium, covered by a copper layer, both layers being deposited by PVD processes. Conventional lithography patterning processes are conducted in conjunction with etching processes to etch the bulk material of the under bump layer to form contact regions (not shown). Electroplating processes are then used to form a pad coating on the under bump metal layer or contact regions by depositing a sequence of metal layers, such as for example a sequence of copper, nickel and gold layers. The pad coating is formed to serve as a bump connector pad 44 which contains a plurality of electrically conducting contact bumps 46 that extend out of the interposer 22 to allow electrical connection to the underlying interconnects 40 and through-silicon vias 28.

In the next process step, an electronic circuit substrate (EC substrate) 50 comprising a plurality of electronic circuits 54 is bonded to the interposer 22 as shown in FIG. 1B. The electronic circuits 54 (also known as active dies) can comprise for example, integrated, display, memory, power, and photovoltaic circuits. The EC substrate 50 comprises a connector surface 56 comprising electrical contacts 58 for electrically connecting the electronic circuits 54 to the bumps 46 of the bump connector pad 44 of the interposer 22. The electrical contacts 58 of the connector surface 56 of the EC substrate 50 are aligned to the bumps 46 or the bump connector pad 44 of the interposer 22, and thereafter, bonded to electrically couple the bumps 46 to the electrical contacts 58 to form electrical connections between the electronic circuits 54 and the through-silicon vias 28 in the interposer 20. The bonding process selected depends upon the pitch or heights of the bumps 46 of the bump connector pad 44. For example, the bonding process can be a reflow bond process to bond large sized bumps 46 which typically have a height of from about less than 30 microns, or even up to about 60 microns, or a thermo-compression bonding process to bond smaller bumps 46 such as copper pillars which typically have a height of less than about 10 microns, or even up to about 30 microns. It should be noted that unlike conventional processes, the EC substrate 50 does not need to be thinned prior to bonding, and retains its original thickness.

After bonding, an under-fill material 48 is injected into the interface gap 57 between the interposer 22 and the EC substrate 50 to seal off the interface gap 57 and form an under-fill interface layer 52. The selected under-fill material 48 and under-filling process depends on the height of the bumps 46 and standoff height between the interposer 22 and the EC substrate 50. Suitable under-fill processes include capillary injection under-fill, no-flow under-fill (NUF), non-conductive paste (NCP), non-conductive fill (NCF), and laminate/spin-on wafer level under-fill (WLUF) processes. Capillary injection under-fill processes are suitable for bumps 46 having higher heights of about 30 microns or even higher than about 60 microns, and larger standoff heights of about 40 microns or even higher than 70 microns. However, NUF, NCP, NCF and WLUF under-fill processes are useful for smaller bumps having heights of less than about 10 microns up to about 30 microns, and smaller standoff heights of less than about 10 microns and up to about 30 microns.

After insertion of the under-fill material 48, the bonded structure 60 comprising the EC substrate 50 and the interposer 22 is molded with a molding compound 62 which covers the electronic circuits 54 to form a molded structure 64 that has better mechanical strength and flatness for subsequent processing steps. A suitable molding compound 62 comprises a molding polymer such as an epoxy or resin compound. A suitable molding process comprises selection of appropriate resin, epoxy or other organic compounds which has a coefficient of thermal expansion (CTE) which substantially matches (less than 10% or even less than 5% difference in CTE's) the CTE of the material of the EC substrate 50 which can be silicon, glass, etc. The molding compound 62 is applied to cover the electronic circuits 54 to a first thickness, as shown in FIG. 1B that is sufficient for the resultant molded structure 64 to have sufficient mechanical strength to withstand subsequent planarization and backside via-reveal processes conducted on the interposer 22. Typically, the molding compound 62 encapsulates the electronic circuits 54 to form a molded structure 64 having a first molded thickness T_{M1} of at least about 750 microns, or even at least about 850 microns.

In one aspect of the present process, the molded structure 64 is thinned and planarized by a chemical-mechanical process (CMP) allowing both the exposed surface of the molding compound 62 and/or the electronic circuits 50 of the EC substrate 50 to be simultaneously thinned without the use of prior art carrier plates bonded to the EC substrate 50. In this step, the molded structure 64 is planarized and thinned to the desired thickness to expose the top surfaces 68 of the embedded electronic circuits 54 and form a thinned EC structure 72. The top surfaces 68 of the electronic circuits 54, can be for example, the surface of an integrated circuit or other structure, which is later bonded to a heat sink 70 for efficient heat dissipation (as shown in FIG. 1F). In this step, the molded structure 64 is thinned to a second molded thickness T_{M2} that is less than the first thickness by at least about 50%, or even at least about 60%, or even about 70%. For example, the molded structure 64 can be thinned to a second molded thickness T_{M2} of from about 350 microns to about 500 microns, or even from about 200 microns to about 400 microns. This thinning process step avoids the conventional bonding/debonding steps in which a carrier plate was bonded and debonded from the interposer 22 and EC substrate 50 prior to conducting any thinning processes to provide mechanical strength to these structures after thinning of the same. Another benefit of thinning the molded structure 64 is that the embedded electronic circuits 54 do not need to be thinned prior to bonding to the interposer 22, and both the molding compound 62 and the electronic circuits 54 of the EC substrate 50 can be simultaneously thinned avoiding multiple thinning and planarization steps, and avoiding carrier bonding steps.

Thereafter, the thinned EC structure 72 is flipped over for thinning and planarization of the bonded interposer 22 as shown in FIG. 10. In this thinning process, the thinned EC structure 72 serves to mechanically support the interposer 22 during thinning of the interposer 22. As result, once again a carrier plate does not need to be bonded to the interposer 24 for thinning of the interposer 22 saving the bonding and de-bonding steps of conventional processes. In this step, the interposer 22 is thinned to a second interposer thickness T_{I2} that is less than its first thickness by at least about 70%, or even at least about 95%. For example, the interposer 22 can be reduced from a thickness of from about 750 microns, or even from about 850 microns to a thickness of about 100 microns. After thinning, a highly etch-selective etching process is conducted to expose contact regions 78 of the through-silicon vias 28 which now protrude from the thinned back surface 82 of the silicon plate 30. After the etching process, a via passivation film (not shown) is deposited over the exposed contact regions 78 of the through-silicon vias 28 to protect the same from atmospheric exposure. The via passivation film can comprise a dielectric material such as a silicon nitride, silicon oxide, or polymer film, which is deposited by plasma enhanced chemical vapor deposition, reflowing, spin-on, or other coating methods.

Thereafter, conventional bump forming processes are used to create contact bumps 80 on the exposed contact regions 78 of the through-silicon vias 28 as shown in FIG. 1E. The conventional bump forming processes can be used to create bumps 80 that constitute a UBM pad, C4 bump or BGA. In this process, a photo-sensitive polymer is deposited on the thinned back surface 82 of the interposer 22 followed, by resist coating and photolithography exposure and development to create exposed contacts 84 through the previously deposited passivation film. Another under bump metal layer (not shown) is deposited by conventional PVD processes on the exposed contacts 84 followed by resist patterning and bump electroplating. The resist pattern is then stripped off and the underlying under bump layer wet etched to create a plurality of contact bumps 80 on the thinned back surface 82 of the interposer 22 to form a thinned EC-interposer structure 90.

In a post-singulation process step, one or more heat sinks 70 are mounted directly on the top surfaces 68 of the electronic circuits 54 before dicing. The heat sinks 70 can also be mounted on the electronic circuits 54 after dicing the thinned EC-interposer structure 90 into individual circuits. The heat sinks 70 are generally used when the electronic circuits 54 are high power devices that utilize power levels of at least about 10 watts, or even at least about 35 watts. Suitable heat sinks comprise aluminum or copper structures with heat dissipating fins.

A second exemplary process (via-last process) in which the through-silicon vias 28a are formed in a later process step through a thinned back surface of an interposer 22a, is illustrated in FIGS. 2A to 2F and the broken arrow path shown in FIG. 3. In this process, the original interposer 22a is not fabricated with through-silicon vias 28a but is simply a silicon plate 30a with a front surface 32a having a bump connector pad 44a, and underlying features 32a such as interconnects 40a and other electrically connecting structures, as shown in FIG. 2A. The fabrication steps for the bump connector pad 44a which contains electrically conducting bumps 46a for electrical connection to the underlying interconnects 40a are the same as those previously described. The interposer 22a also has a back surface 34a and a first interposer thickness T_{I1} that is typically the full or original thickness of the original silicon plate 30a but can also be a smaller thickness. A typical first thickness of the silicon plate 30a is from about 500 to about 1000 microns.

An electronic circuit substrate (EC substrate) 50 comprising a plurality of electronic circuits 54 is bonded to the interposer 22a as shown in FIG. 2B. The EC substrate 50 comprises a connector surface 56 comprising electrical contacts 58 which are aligned to the bumps 46a of the bump connector pad 44a of the interposer 22a, and thereafter, bonded to electrically couple the bumps 46a to the electrical contacts 58 to form electrical connections between the electronic circuits 54 and the subsequently formed (via-last) through-silicon vias 28a in the interposer 22a. After bonding, an under-fill material 48 is injected into the interface gap 57 between the interposer 22 and the EC substrate 50 to seal off the interface gap 57 and form an under-fill interface layer 52. After insertion of the under-fill material 48, the bonded structure 60a comprising the EC substrate 50 and the interposer 22a is molded with a molding compound 62 to cover the electronic circuits 54 and form a molded structure 64a.

In the next step, the molded structure 64a is thinned and planarized by a chemical-mechanical process (CMP) as shown in FIG. 2C. The thinning process allows both the molding compound 62 and/or the electronic circuits 50 of the EC substrate 50 to be simultaneously thinned without the use of carrier plates. In this step, the molded structure 64a is planarized and thinned to a second molded thickness T_{M2} from the original molding thickness T_{M1}, as described above, to expose the top surfaces 68 of the electronic circuits 54.

Thereafter, the thinned EC structure 72a is flipped over for thinning and planarization of the bonded partially formed interposer 22a as shown in FIG. 2D. In this thinning process, the thinned EC structure 72A serves to mechanically support the interposer 22A during thinning of the interposer 22A without use of a carrier plate. The interposer 22a is thinned to a second interposer thickness T_{I2} that is less than the first interposer thickness T_{I1} by at least about 70%, or even at least about 95%. For example, the interposer 22a can be reduced from a thickness of about 750 microns, to a thickness of from about 50 to about 200 microns.

Thereafter, a backside (via-last) lithography and etching process is performed to etch through the thinned back surface 82a of the silicon plate 30 to form etched holes 100 which selectively land on the underlying interconnects 40. The etching process to form the holes 100 of the via-last process is highly selective to achieve uniform etching hole depths across the silicon plate 30a and stop on the underlying interconnects 40a which are thin and can be etched off. Thereafter, a conformal oxide liner (not shown) is deposited into the etched holes 100 to electrically insulate the subsequently formed through-silicon vias 28a. A suitable oxide liner deposition process comprises a low temperature CVD process which deposits silicon nitride, silicon oxide, or polymer at temperatures of for example, less than 270° C., or even less than 230° C.—which is the temperature limit set by the solder reflow temperature to maintain the integrity of the electrically coupling bond between the bumps 46a of the bump connector pad 44a of the interposer 22a and the electrical contacts 58 of the connector surface 56 of the electronic circuit substrate 50. Subsequently, a barrier/seed layer is deposited into the etched holes 100 using a temperature controlled PVD process, followed by etching and cleaning of the bottom surface of the holes 100 to remove the deposited liner material for electrical contact to the underlying interconnects 40a. In the next step of the via-last process, an electroplating process is used to fill the etched holes 100 with an electrically conductive material, such as aluminum or copper, to finish the through-silicon vias 28a. Surrounding portions of the thinned back surface 82a of the silicon plate 30a are covered with a resist material. The via-last process provides additional process efficiencies by eliminating a CMP polishing step for planarizing the exposed portions of conventional through-silicon vias and subsequent bump electroplating processes.

In the present process, the contact bumps 80a are formed by electroplating a monolithic layer onto the back surface of the interposer 22a immediately after or in the same electroplating process as that used to fill the etched holes 100 of the through-silicon vias 28a with electroplated material. A resist layer (not shown) is then patterned over the monolithic electroplated layer, etched to form the contact bumps 100, and then residual resist is stripped off, and the contact bumps 80a wet etched to provide the via-last process structure shown in FIG. 2E. In this manner, the via-last process also the electroplating process for forming the contact bumps 80a to be performed monolithically immediately after the electroplating process for filling the through-silicon vias 28a thereby avoiding additional process steps such as a PVD deposition process for depositing under-bump material. Thereafter, one or more heat sinks 70 can be attached to the exposed top surfaces 68 of the electronic circuits 54 to form the finished 3D chip stack 30 as shown FIG. 2F.

Although exemplary embodiments of the present invention are shown and described, those of ordinary skill in the art may devise other embodiments which incorporate the present invention and which are also within the scope of the present invention. Furthermore, the terms “below”, “above”, “bottom”, “top”, “up”, “down”, “first” and “second”, and other relative or positional terms are shown with respect to the exemplary embodiments in the FIGS. and are interchangeable. Therefore, the appended claims should not be limited to the descriptions of the preferred versions, materials, or spatial arrangements described herein to illustrate the invention.

What is claimed is:

1. A method of fabricating a 3D chip stack, the method comprising:
(a) providing an interposer having a first interposer thickness and a front surface comprising bumps;
(b) providing an electronic circuit substrate comprising a plurality of electronic circuits and a connector surface having electrical contacts;
(c) bonding and electrically coupling the electrical contacts of the connector surface of the electronic circuit substrate to the bumps of the interposer;
(d) applying a molding compound over the electronic circuits to form a molded structure having a first molded thickness;
(e) thinning the molded structure to have a second molded thickness that is less than the first molded thickness; and
(f) thinning the interposer to form a thinned interposer having a second interposer thickness that is less than the first interposer thickness.

2. A method according to claim 1 wherein (e) comprises thinning the molded structure to a second molded thickness is less than a first molded thickness by at least about 50%.

3. A method according to claim 1 wherein (f) comprises thinning the interposer from a back surface of the interposer and to a second interposer thickness is less than a first interposer thickness by at least about 70%.

4. A method according to claim 1 wherein (d) further comprises injecting an under-fill material into an interface gap between the interposer and the electronic circuit substrate.

5. A method according to claim 1 wherein in (a) the interposer comprises a plurality of through-silicon vias.

6. A method according to claim 1 wherein in (a) the interposer comprises a plurality of through-silicon vias, and wherein (f) comprises thinning the interposer to expose contact regions of the through-silicon vias.

7. A method according to claim 1 further comprising, after (f), forming a plurality of through-silicon vias in the interposer by etching holes through a thinned back surface of the thinned interposer and depositing an oxide liner and metal into the etched holes.

8. A method of fabricating a 3D chip stack, the method comprising:
(a) providing an interposer having a first interposer thickness, a front surface comprising bumps, a plurality of through-silicon vias, and a back surface;
(b) providing an electronic circuit substrate comprising a plurality of electronic circuits and a connector surface having electrical contacts;
(c) bonding and electrically coupling the electrical contacts of the connector surface of the electronic circuit substrate to the bumps of the interposer;
(d) applying a molding compound over the electronic circuits to form a molded structure having a first molded thickness;
(e) thinning the molded structure to a second molded thickness that is less than the first molded thickness and to expose top surfaces of the electronic circuits; and
(f) thinning the interposer from its back surface to form a thinned interposer having a second interposer thickness that is less than the first interposer thickness and to expose contact regions of the through-silicon vias.

9. A method according to claim 8 wherein (e) comprises thinning the molded structure to a second molded thickness is less than a first molded thickness by at least about 50%.

10. A method according to claim 8 wherein (f) comprises thinning the interposer a second interposer thickness is less than a first interposer thickness by at least about 70%.

11. A method according to claim 8 wherein (d) further comprises injecting an under-fill material into an interface gap between the interposer and the electronic circuit substrate.

12. A method of fabricating a 3D chip stack, the method comprising:
(a) providing an interposer having a first interposer thickness and a front surface comprising bumps;
(b) providing an electronic circuit substrate comprising a plurality of electronic circuits and a connector surface having electrical contacts;
(c) bonding and electrically coupling the electrical contacts of the connector surface of the electronic circuit substrate to the bumps of the interposer;
(d) applying a molding compound over the electronic circuits to form a molded structure having a first molded thickness;
(e) thinning the molded structure to a second molded thickness that is less than the first molded thickness and to expose top surfaces of the electronic circuits;
(f) thinning the interposer to from a thinned interposer having a second interposer thickness that is less than the first interposer thickness; and
(g) forming a plurality of through-silicon vias in the thinned interposer by etching holes through a back surface of the thinned interposer and depositing an oxide liner and metal into the etched holes.

13. A method according to claim 12 wherein (e) comprises thinning the molded structure to a second molded thickness is less than a first molded thickness by at least about 50%.

14. A method according to claim 12 wherein (f) comprises thinning the interposer to form a thinned interposer having a second interposer thickness is less than a first interposer thickness by at least about 70%.

15. A method according to claim 12 wherein (d) further comprises injecting an under-fill material into an interface gap between the interposer and the electronic circuit substrate.
